(19) United States
(12) Patent Application Publication
(10) Pub. No.: US 2011/0222355 A1
(43) Pub. Date: Sep. 15, 2011

(54) Control voltage generation circuit and nonvolatile storage device having the same

(75) Inventors: Chieko Nakashima, Nagasaki (JP); Tomohiro Namise, Nagasaki (JP); Tsunenori Shiimoto, Kanagawa (JP)

(73) Assignee: Sony Corporation, Tokyo (JP)

(21) Appl. No.: 13/064,009

(22) Filed: Mar. 2, 2011

(30) Foreign Application Priority Data
Mar. 11, 2010 (JP) P2010-054199
Nov. 22, 2010 (JP) P2010-259714

(51) Int. Cl. G11C 5/14; H03L 5/00

(52) U.S. Cl. 365/189.09; 327/315

(57) ABSTRACT

Disclosed herein is a control voltage generation circuit including: a reference voltage generation circuit adapted to generate a reference voltage; and a voltage conversion circuit adapted to generate, based on the reference voltage, a control voltage to be supplied to the gate of a clamping transistor connected between a bit line and a sense amplifier to adjust the voltage of the bit line, wherein the voltage conversion circuit outputs a voltage, which is the sum of a voltage proportional to the reference voltage and a voltage equivalent to the threshold voltage of the clamping transistor, to the gate of the clamping transistor as the control voltage.

### BACKGROUND OF THE INVENTION

1. Field of the Invention

The present invention relates to a control voltage generation circuit and nonvolatile storage device having the same and, more particularly, to a control voltage generation circuit for generating a control voltage supplied to the gate of a clamping transistor connected between a bit line and sense amplifier and a nonvolatile storage device having the same.

2. Description of the Related Art

High density DRAMs (Dynamic Random Access Memories) capable of high speed operation are widely used for information devices such as computers. However, the manufacturing process of a DRAM is more complicated than that of common logic circuits and signal processing circuits for electronic devices, thus resulting in high manufacturing cost. Further, a DRAM requires frequent refresh cycles because it is a volatile memory that loses its information when power is removed.

Therefore, nonvolatile semiconductor storage devices (nonvolatile storage devices) are widely used that do not lose their information even when power is removed. Among known nonvolatile storage devices are flash memory, FeRAM (Ferroelectric Random Access Memory) and MRAM (Magnetoresistive Random Access Memory). An MRAM is a resistance change nonvolatile storage device that is drawing attention, for example, for its potential for operation at higher speed.

On the other hand, a new type of nonvolatile storage device has been proposed as a resistance change nonvolatile storage device that is advantageous in overcoming the limitations in microfabrication of memory cells. A memory cell in this nonvolatile storage device has an ionic conductor containing a particular metal sandwiched between two electrodes. One of the two electrodes contains the metal contained in the ionic conductor. When a voltage is applied between the two electrodes, the metal contained in the electrode diffuses in the ionic conductor in the form of ions, changing the electrical characteristics of the ionic conductor such as resistance (see JP-T-2002-536840, hereinafter referred to as Patent Document 1).

Incidentally, in a nonvolatile storage device, data is read from a memory cell by amplifying the signal read to a bit line from the memory cell with a sense amplifier. A clamping transistor is provided between the sense amplifier and bit line to adjust the bit line voltage. A control voltage is applied from a control voltage generation circuit to the gate of the clamping transistor to read data from the memory cell. This adjusts the bit line voltage (refer to Patent Document 1).

A specific description will be given here of the configuration of a data read circuit adapted to read data from a memory cell. FIG. 10 illustrates the configuration of a data read circuit for an existing nonvolatile storage device.

As illustrated in FIG. 10, a data read circuit includes a control voltage generation circuit 51, sense amplifier 52, clamping transistors QN51 and QN52, column selection transistors QN53 and QN54 and reference cell RC.

The one column selection transistor QN53 is connected between the clamping transistor QN51 and a bit line BL to read a signal commensurate with the data stored in a memory cell MC selected in a word line as a target memory cell into the sense amplifier 52 via the clamping transistor QN51.

On the other hand, the other column selection transistor QN54 is connected between the clamping transistor QN52 and reference cell RC to read a signal commensurate with the data stored in the reference cell RC into the sense amplifier 52 via the clamping transistor QN52.

The sense amplifier 52 compares the signal read from the memory cell MC against that read from the reference cell RC and outputs a signal commensurate with the comparison result. This allows for data to be read from the memory cell MC. It should be noted that the sense amplifier 52 includes an operational amplifier OP52 and diode-connected PMOS transistors QP53 and QP54.

The clamping transistor QN51 is provided to keep the increase in voltage of the bit line BL to a minimum. This clamping transistor QN51 keeps the voltage of the bit line BL to a potential where the data stored in the memory cell MC is not rewritten during data read from the memory cell MC.

A description will be given here of the control voltage generation circuit 51 adapted to generate a control voltage applied to the gate of the clamping transistor QN51 so as to control the voltage of the bit line BL.

The control voltage generation circuit 51 includes a reference voltage generation circuit 60 and voltage conversion circuit 61. A reference voltage Vref generated by the reference voltage generation circuit 60 is fed to the voltage conversion circuit 61 where a control voltage Vcp commensurate with the reference voltage Vref is generated. This control voltage Vcp is applied to the gate of the clamping transistor QN51. It should be noted that the reference voltage Vref is independent of variations in temperature and source voltage, and that the reference voltage Vref includes, for example, a BGR (Band Gap Reference) circuit.

The voltage conversion circuit 61 includes an operational amplifier OP51, PMOS transistors QP51 and QP52 and resistors R51 and R52. The reference voltage Vref is fed to the inverted input terminal of the operational amplifier OP51, and the non-inverted input terminal thereof is connected to a node N51 (connection node between the drain of the PMOS transistor QP51 and one end of the resistor R51). On the other hand, a source voltage Vcc is fed to the source of the PMOS transistor QP51, and the gate of the PMOS transistor QP51 is connected to the output terminal of the operational amplifier OP51. The other end of the resistor R51 is connected to ground.

Therefore, feedback control is performed so that the voltage of the node N51 becomes equal to the reference voltage Vref. A current 151 flowing through the resistor R51 can be expressed by the following equation:

I51=Vref/R51

On the other hand, the PMOS transistor QP51 forms a current mirror with the PMOS transistor QP52. Therefore, as long as the PMOS transistors QP51 and QP52 are identical in size, the same current flows through the two PMOS transistors QP51 and QP52. Therefore, the control voltage Vcp generated at a node N52 between the PMOS transistor QP52 and resistor R52 can be expressed by the following equation:

Vcp=Vref×(R52/R51)

The gates of the clamping transistors QN51 and QN52 are driven by this control voltage Vcp. At this time, a bias potential VBL of the bit line BL can be expressed by the following equation where Vth is the threshold voltage of the clamping transistors QN51 and QN52:

VBL=Vcp−Vth=Vref×(R52/R51)−Vth

This type of circuit controls the bit line potential VBL with high accuracy thanks not only to the voltage Vref that remains constant regardless of variations in source voltage and temperature but also to a given resistance ratio (R52/R51).

For more information, refer to Japanese Patent Laid-Open Publication No. 2006-351193.

### SUMMARY OF THE INVENTION

In the above resistance change nonvolatile storage device, a bit line voltage may cause data corruption due to variations between memory cells or deterioration of the memory cells even if this voltage is a weak bias voltage as used to read data from a memory cell. Therefore, a voltage sufficiently lower than the source voltage must be applied to the bit lines when data is read from a memory cell.

However, the existing type of read circuit is subject to performance variations caused by temperature and process variations including variations in a threshold voltage Vth of the clamping transistors, making the controllability of extremely small voltages questionable.

In light of the foregoing, it is an aim of the present invention to provide a control voltage generation circuit capable of minimizing the impact of variations in the threshold voltage of clamping transistors and a nonvolatile storage device having the same.

In order to achieve the above aim, a first embodiment according to the present invention is a control voltage generation circuit that includes a reference voltage generation circuit and voltage conversion circuit. The reference voltage generation circuit generates a reference voltage. The voltage conversion circuit generates, based on the reference voltage, a control voltage to be supplied to the gate of a clamping transistor. The clamping transistor is connected between a bit line and a sense amplifier to adjust the voltage of the bit line. The voltage conversion circuit outputs a voltage, which is the sum of a voltage proportional to the reference voltage and a voltage equivalent to the threshold voltage of the clamping transistor, to the gate of the clamping transistor as the control voltage.

The control voltage generation circuit of the first embodiment may include variable resistors adapted to adjust the control voltage.

Further, another embodiment according to the invention is a nonvolatile memory device that includes a memory cell array, word lines, bit lines, sense amplifiers, clamping transistors and control voltage generation circuit. The memory cell array has memory cells arranged in a matrix form. Each of the word lines is connected to the memory cells in the same row. Each of the bit lines is connected to the memory cells in the same column. A signal read from the memory cell connected to the word line in the row selected as the target row via the bit line is fed to one of the input terminals of each of the sense amplifiers. A signal read from a reference cell is fed to the other input terminal of the sense amplifier. Each of the clamping transistors is connected between one of the sense amplifiers and one of the bit lines and adjusts the voltage of the bit line by using a control voltage applied to the gate. The control voltage generation circuit generates the control voltage. The control voltage generation circuit includes a reference voltage generation circuit and voltage conversion circuit. The reference voltage generation circuit generates a reference voltage. The voltage conversion circuit outputs a voltage, which is the sum of a voltage proportional to the reference voltage and a voltage equivalent to the threshold voltage of the clamping transistor, to the gate of the clamping transistor as the control voltage.

In the nonvolatile memory device, the voltage conversion circuit may include variable resistors adapted to adjust the control voltage.

The present invention applies a voltage, which is the sum of a voltage proportional to the reference voltage and a voltage equivalent to the threshold voltage of the clamping transistor, to the gate of the clamping transistor as the control voltage, thus minimizing the impact of variations in threshold voltage of the clamping transistor.

### BRIEF DESCRIPTION OF THE DRAWINGS

FIG. 1 is a diagram for describing the outline of a data read circuit in a nonvolatile storage device according to an embodiment of the present invention;

FIG. 2 is a diagram illustrating the configuration of the nonvolatile storage device according to the present embodiment;

FIG. 3 is a diagram illustrating the configuration of the data read circuit in the nonvolatile storage device according to the present embodiment;

FIG. 4 is a diagram illustrating a specific example of a variable resistor made up of MOS transistors;

FIG. 5 is a simplified diagram illustrating the configuration of the data read circuit according to the present embodiment;

FIG. 6 is a simplified diagram illustrating the configuration of the data read circuit in another specific example according to the present invention;

FIG. 7 is a diagram illustrating means for changing the capability of a PMOS transistor with a gate width;

FIG. 8 is a diagram illustrating means for changing the capability of another PMOS transistor with another gate width;

FIG. 9 is a diagram describing the intermittent operation of the data read circuit in the present specific example; and

FIG. 10 is a diagram illustrating the configuration of the data read circuit in an existing nonvolatile storage device.

### DETAILED DESCRIPTION OF THE PREFERRED EMBODIMENT

A description will be given below of a mode for carrying out the present invention (hereinafter referred to as an embodiment) with reference to the accompanying drawings. It should be noted that the description will be given in the following order:

1. Outline of the data read circuit (outline of the control voltage generation circuit)
2. Specific configuration of the nonvolatile storage device
3. Specific configuration of the data read circuit
4. Another configuration of the data read circuit

### [1. Outline of the Data Read Circuit]

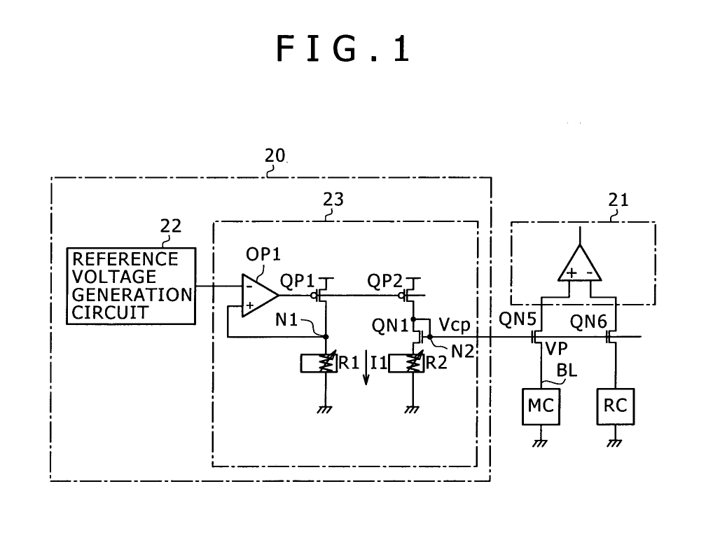

A description will be given first of the outline of a data read circuit in a nonvolatile storage device according to the present embodiment with reference to the accompanying drawings. FIG. 1 is a diagram for describing the outline of the data read circuit in the nonvolatile storage device according to the present embodiment.

As with the existing nonvolatile storage device, the nonvolatile storage device according to the present embodiment adjusts the voltage of each bit line by using a clamping transistor. A voltage conversion circuit adapted to generate, based on the reference voltage, the control voltage Vcp to be applied to the clamping transistor has characteristic features.

As illustrated in FIG. 1, a voltage conversion circuit 23 according to the present embodiment differs from the existing voltage conversion circuit in that an NMOS transistor QN1 is provided and that resistors R1 and R2 are variable resistors.

That is, providing the diode-connected NMOS transistor QN1 minimizes variations in voltage of the bit line BL caused by variations in the threshold voltage Vth of a clamping transistor QN5. On the other hand, using variable resistors as the resistors R1 and R2 minimizes variations in voltage of the bit line BL caused by variations in current driving capability of the memory cell MC. It should be noted that reference numeral 20 denotes the control voltage generation circuit.

A description will be given first of the minimization of variations in voltage of the bit line BL by providing the diode-connected NMOS transistor QN1.

In the voltage conversion circuit 23, the reference voltage Vref is fed to the inverted input terminal of an operational amplifier OP1 from a reference voltage generation circuit 22, and a node N1 is connected to the non-inverted input terminal of the same amplifier OP1 as in the existing voltage conversion circuit. The node N1 is the connection point between the drain of a PMOS transistor QP1 and the resistor R1. The PMOS transistor QP1 has its gate connected to the output terminal of the operational amplifier OP1. Therefore, the voltage of the node N1 is adjusted by feedback control so that the voltage thereof becomes equal to the reference voltage Vref.

As described above, feedback control is performed so that the voltage of the node N1 becomes equal to the reference voltage Vref. Therefore, a current I1 flowing through the resistor R1 can be expressed by the following equation:

I1=Vref/R1

Further, the voltage conversion circuit 23 includes a PMOS transistor QP2 and the resistor R2 as in the existing circuit. Still further, the same circuit 23 includes the NMOS transistor QN1 between the PMOS transistor QP2 and resistor R2. The NMOS transistor QN1 has its gate and drain connected together to form a diode connection.

The PMOS transistor QP2 forms a current mirror with the PMOS transistor QP1. The PMOS transistor QP2 has its drain connected to the resistor R2 via the drain and source of the NMOS transistor QN1. Here, the PMOS transistors QP1 and QP2 are identical in size. Therefore, the same current flows through the PMOS transistors QP1 and QP2. Therefore, the control voltage Vcp generated in the node N2 can be expressed by the following equation where Vth1 is the threshold voltage of the NMOS transistor QN1:

Vcp=Vref×(R2/R1)+Vth1

When the control voltage Vcp is applied to the gate of the NMOS transistor QN5, i.e., a clamping transistor, a voltage Vb applied to the bit line BL can be expressed by Equation 1 shown below where Vth2 is the threshold voltage of the NMOS transistor QN5.

Vb=Vcp−Vth2=Vref×(R2/R1)+Vth1−Vth2 (1)

Here, if, for example, the NMOS transistors QN1 and QN5 are identical in size so that the threshold voltages Vth1 and Vth2 are the same, the voltage Vb applied to the bit line BL can be expressed by Equation 2 shown below.

Vb=Vcp−Vth2=Vref×(R2/R1) (2)

This makes it possible to ignore the impact of variations in capabilities of the NMOS transistor QN5, i.e., a clamping transistor, and particularly variations in the threshold voltage Vth2 thereof. Further, if the resistors R1 and R2 are identical in resistance, Vb can be made equal to Vref.

As described above, when data is read from the memory cell MC, that is, when an extremely small voltage sufficiently lower than the source voltage is applied to the bit line BL, minimizing the impact of variations in capabilities of the clamping transistor QN5 provides highly accurate control. This prevents data corruptions such as erroneous rewriting of data stored in the memory cell MC.

A description will be given next of the minimization of variations in voltage of the bit line BL caused by variations in current driving capability of the memory cell MC by using variable resistors as the resistors R1 and R2.

In some resistance change nonvolatile storage devices such as PRAM and ReRAM, the resistance of the memory cell MC changes by two to three orders of magnitude between the low and high resistance states. In such a case, the current driving capability of the memory cell MC also changes with change in resistance of the memory cell MC. In order to control the voltage of the bit line BL with high accuracy, it is necessary to respond also to this change in current driving capability.

However, although capable of applying a constant voltage to the clamping transistor adapted to clamp the bit line voltage, an existing control voltage generation circuit is unable to respond to variations in current driving capability of the memory cell MC.

For this reason, the reference voltage generation circuit 22 according to the present embodiment uses variable resistors as the resistors R1 and R2 so that the resistances of these resistors can be controlled. This makes it possible for the reference voltage generation circuit 22 to respond, for example, to variations in resistive component of the memory cell MC (current driving capability).

That is, as shown in Equations 1 and 2, the voltage Vb of the bit line BL is determined based on the resistances of the resistors R1 and R2. Therefore, variable resistors are used as the resistors R1 and R2 so that the resistances of these resistors can be controlled, thus making it possible to adjust the voltage Vb of the bit line BL.

As a result, even in the event of variations in resistive component of the memory cell MC, it is possible to minimize data corruptions such as erroneous change of data stored in the memory cell MC by adjusting the voltage Vb of the bit line BL with high accuracy.

It should be noted that only one of the resistors R1 and R2 may be a variable resistor, with the other resistor being a fixed resistor. However, using variable resistors as both the resistors R1 and R2 makes it easier to adjust the voltage Vp of the bit line BL and also makes it possible to adjust the voltage Vp with high accuracy.

It should be noted that the same storage element as the memory cell MC may be used as the resistors R1 and R2. This allows for the voltage of the bit line BL to be more responsive, thus making the reference voltage generation circuit 22 more immune to process variations. For example, the resistance change memory cell MC includes a nonvolatile resistance change element and NMOS transistor (selection transistor). However, the resistance of the resistance change element is not linear with respect to the voltage applied across the same element. In order to apply a given voltage to the memory cell MC via the bit line BL, resistance elements such as common polysilicon resistors have been used in the existing control voltage generation circuit. These resistance elements have a linear bias dependence. However, the resistor elements used in the memory cell MC differ in process variations and voltage dependence from those used in the control voltage generation circuit, thus resulting in reduced controllability of the voltage of the bit line BL. For this reason, the reference voltage generation circuit 22 uses the same storage element as in the memory cell MC as the resistors R1 and R2. For example, the resistance change memory cell MC uses resistance change elements as the resistors R1 and R2. This provides improved controllability of the voltage of the bit line BL.

### [2. Specific Configuration of the Nonvolatile Storage Device]

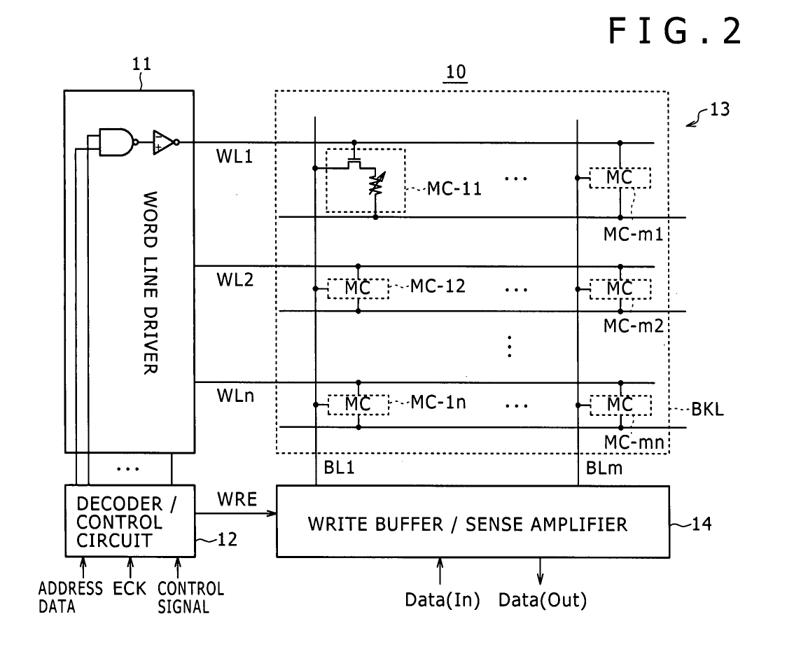

A description will be given next of the configuration of the nonvolatile storage device according to the present embodiment with reference to the accompanying drawing. FIG. 2 is a diagram illustrating the configuration of the nonvolatile storage device according to the present embodiment.

A nonvolatile storage device 10 shown in FIG. 2 includes, for example, a plurality of word line driver circuits 11, a decoder/control circuit 12, memory cell array 13 and write buffer/sense amplifier 14. It should be noted that the memory cell array 13 includes a plurality of memory blocks BKL.

Here, only one word line driver (which includes a NAND circuit and inverter circuit) and one memory block BKL are shown for simplification of the description. Practically, however, there are a predetermined number of memory blocks that are provided one for a predetermined number of word lines WL (WL1, WL2 and so on). It should be noted that the memory cells MC (MC-11, MC-12 and so on) in the same row are connected to one of the word lines WL.

The decoder/control circuit 12 includes a predecoder, internal timing control circuit and other components to decode input address data and generate, for example, an internal clock signal and control signal based on an external clock ECK.

The decoder includes not only a row address decoder but also a column address decoder. The column address decoder selects a column address based on the input address data.

On the other hand, the control circuit is supplied with an external control signal and the external clock ECK for operation. For example, the control circuit decodes a write or read enable signal, supplies the decoded signal to the predecoder and word line driver circuit 11 so as to allow decoding of the address signal and activates or deactivates the word line WL. Further, the control circuit generates a clock, outputs a write enable signal to the write buffer/sense amplifier 14 to control the write timing and outputs a read enable signal to the write buffer/sense amplifier 14 to control the read timing. Still further, the control circuit outputs a sense amplifier enable signal to a sense amplifier 21 adapted to amplify data in the bit line BL. Still further, the control circuit outputs a timing signal used to control a column address output from the column decoder.

The predecoder selects one of the word line driver circuits 11 so that the clock and other signals output from the decoder/control circuit 12 are supplied to the selected word line driver circuit 11. In the block to which the selected word line driver circuit 11 belongs, if the decoder is, for example, three bits wide, a high-level voltage is supplied to one of the eight word lines WL to activate this word line. At the same time, a low-level voltage is supplied to the other word lines WL to deactivate these word lines.

The memory cell array 13 includes the plurality of memory cells MC-11 to MC-mn arranged in a matrix form. Each of the word lines WL is connected to the memory cells MC in the same row. Each of the bit lines BL is connected to the memory cells MC in the same column. For example, the memory cells MC-11 to MC-m1 are connected to the same word line WL1, and the memory cells MC-11 to MC-1n are connected to the same bit line BL1. When used in a resistance change nonvolatile storage device, these memory cells MC each have a resistance change element.

During data write, the write buffer/sense amplifier 14 is supplied with a write enable signal, column select signal, input data Data and other signals. When one of the bit lines BL is selected by a column select signal, data is written to the memory cell MC via the write buffer circuit. Further, during data read, the write buffer/sense amplifier 14 amplifies the data output to the bit line BL from the selected memory cell MC and outputs the data via its output buffer.

### [3. Specific Configuration of the Data Read Circuit]

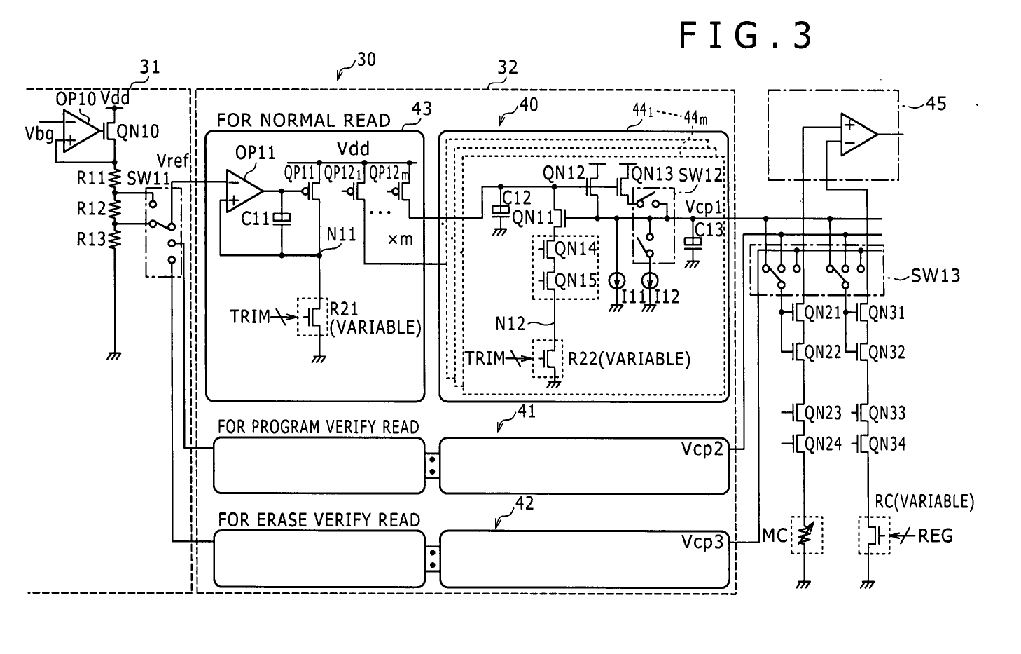

A description will be given next of a specific example of the data read circuit in the nonvolatile storage device 10 according to the present embodiment with reference to the accompanying drawings. FIG. 3 is a diagram illustrating the configuration of the data read circuit in the nonvolatile storage device 10 according to the present embodiment.

As illustrated in FIG. 3, the data read circuit includes a control voltage generation circuit 30, sense amplifier 45, clamping transistors QN21 and QN22, column selection transistors QN23 and QN24 and other components. The control voltage generation circuit 30 includes a reference voltage generation circuit 31 and voltage conversion circuit 32. The data read circuit also includes not only the reference cell RC but also clamping transistors QN31 and QN32 and column selection transistors QN33 and QN34 so that the reference cell RC has a data read path comparable to that of the memory cell MC.

The reference voltage generation circuit 31 has a band gap reference circuit (not shown) using a CMOS process and generates the reference voltage Vref based on a low-voltage and high-accuracy band gap reference voltage Vbg output from the band gap reference circuit.

The reference voltage generation circuit includes an operational amplifier OP10, NMOS transistor QN10 and resistors R11 to R13 and can output, based on the band gap reference voltage Vbg, two voltages Vref1 and Vref2 that are different in voltage level.

More specifically, the band gap reference voltage Vbg is fed to the inverted input terminal of the operational amplifier OP10, and the source of the NMOS transistor QN10 is connected to the non-inverted input terminal of the same amplifier OP10. Further, the source voltage Vdd is fed to the drain of the NMOS transistor QN10, and the gate of the same transistor QN10 is connected to the output terminal of the operational amplifier OP10. As a result, feedback control is performed so that the source voltage of the NMOS transistor QN10 becomes equal to the band gap reference voltage Vbg.

Further, the resistors R11 to R13 are connected in series between the source of the NMOS transistor QN10 and ground. The first reference voltage Vref1 can be output as the reference voltage Vref from the connection node between the resistors R11 and R12, and the second reference voltage Vref2 can be output as the reference voltage Vref from the connection node between the resistors R12 and R13. The reference voltages Vref (first and second reference voltages Vref1 and Vref2) are not dependent on variations in the source voltage Vdd or temperature. The reference voltage generation circuit 31 has a switch SW11 adapted to select which of the first and second reference voltages Vref1 and Vref2 is to be output as the reference voltage Vref. The switch SW11 is controlled by the write buffer/sense amplifier 14 to select the voltage commensurate with the voltage level required to be applied to the bit line BL.

The voltage conversion circuit 32 includes first, second and third voltage conversion circuits 40, 41 and 42. The first voltage conversion circuit 40 generates a control voltage Vcp1 for use during normal data read from the memory cell MC. The second voltage conversion circuit 41 generates a control voltage Vcp2 adapted to verify whether data has been properly written to the memory cell MC after data write to the memory cell MC. On the other hand, the third voltage conversion circuit 42 generates a control voltage Vcp3 adapted to verify whether data has been properly erased from the memory cell MC after data erasure by overwriting. The first, second and third voltage conversion circuits 40, 41 and 42 are configured in the same manner, and the description of the second and third voltage conversion circuits 41 and 42 will be omitted in the description given below.

The first voltage conversion circuit 40 includes first and second regulator sections 43 and 44 (44₁ to 44ₘ). The second regulator sections 44 are provided, one for each of the bit lines BL.

The first regulator section 43 includes an operational amplifier OP11, resistor R21, PMOS transistor QP11, a plurality of PMOS transistors QP12 (QP12₁ to QP12ₘ) and a MOS capacitor C11. The PMOS transistors QP12 are provided, one for each of the second regulator sections 44.

The reference voltage Vref is fed to the inverted input terminal of the operational amplifier OP11 from the reference voltage generation circuit 31, and the non-inverted input terminal of the same amplifier OP11 is connected to a node N11. The node N11 is the connection point between the drain of the PMOS transistor QP11 and one end of the resistor R21. Further, the gate of the PMOS transistor QP11 is connected to the output terminal of the operational amplifier OP11. This configuration allows for feedback control to be performed so that the voltage of the node N11 becomes equal to the reference voltage Vref. It should be noted that the MOS capacitor C11 is provided between the output terminal of the operational amplifier OP11 and the node N11 for stable feedback control. Further, the source voltage Vdd is fed to the source of the PMOS transistor QP11, and the other end of the resistor R21 is connected to ground.

The output terminal of the operational amplifier OP11 is connected to the gates of the plurality of PMOS transistors QP12₁ to QP12ₘ. Each of the PMOS transistors QP12₁ to QP12ₘ forms a current mirror with the PMOS transistor QP11. This allows for a current commensurate with the resistance of the resistor R21 to flow through each of the PMOS transistors QP12₁ to QP12ₘ. Here, the PMOS transistors QP11 and QP12₁ to QP12ₘ are identical in size so that the same current flows through all of the PMOS transistors QP11 and QP12₁ to QP12ₘ. At this time, the current flowing through the PMOS transistors QP12₁ to QP12ₘ is determined by the resistance of the resistor R21 and the reference voltage Vref. It should be noted that these transistors need not necessarily be identical in size. That is, the size ratio of the PMOS transistor QP11 to each of the PMOS transistors QP12₁ to QP12ₘ may be 1:k (where k is other than 1). In this case, the current flowing through each of the PMOS transistors QP12₁ to QP12ₘ is determined by the resistance of the resistor R21, the transistor size ratio (1:k) and the reference voltage Vref.

As described above, the first regulator section 43 supplies a current commensurate with the resistance of the resistor R21 and the reference voltage Vref to each of the second regulator sections 44.

Each of the second regulator sections 44 includes NMOS transistors QN11 to QN15, constant current sources I11 and I12, switch SW12 and MOS capacitors C12 and C13.

The current supplied from the first regulator section 43 flows into the NMOS transistors QN11, QN14 and QN15 and a resistor R22 that are connected in series between the input of each of the second regulator sections 44 and ground.

The NMOS transistors QN14 and QN15 are provided to cancel out the voltage generated between the sense amplifier 45 and bit line BL by the column selection transistors QN23 and QN24 which will be described later. The NMOS transistors QN14 and QN15 are identical in size to the column selection transistors QN23 and QN24. It should be noted that the same holds true for the column selection transistors QN33 and QN34. The NMOS transistors QN14 and QN15 turn ON during data read from the memory cell MC as with the column selection transistors QN23, QN24, QN33 and QN34.

On the other hand, the drain and gate of the NMOS transistor QN11 are connected together via the gate and source of the NMOS transistor QN12. These NMOS transistors QN11 and QN12 cancel out the voltage generated between the sense amplifier 45 and bit line BL by the clamping transistors QN21 and 022.

The NMOS transistor QN13, switch SW12 and constant current source I12 provided in each of the second regulator sections 44 are designed to adjust the generated control voltage Vcp1. If the current supplied from the first regulator section 43 is generated based on the second reference voltage Vref2 rather than the first reference voltage Vref1, the switch SW12 is switched ON by an unshown control circuit. This connects the source of the NMOS transistor QN13 and the constant current source I12 to the gate of the NMOS transistor QN11, thus allowing for the generated control voltage Vcp1 to be adjusted.

The control voltage Vcp1 output from each of the second regulator sections 44 of the voltage conversion circuit 32 is connected to the gates of the clamping transistors QN21, QN22, QN31 and QN32.

The non-inverted input terminal of the sense amplifier 45 is connected to the bit line BL via the clamping transistors QN21 and QN22 and column selection transistors QN23 and QN24. This terminal receives the signal read from the memory cell MC connected to the bit line BL via the same line BL.

On the other hand, the inverted input terminal of the sense amplifier 45 is connected to the reference cell RC via the clamping transistors QN31 and QN32 and column selection transistors QN33 and QN34. This terminal receives the voltage commensurate with the voltage generated by the reference cell RC.

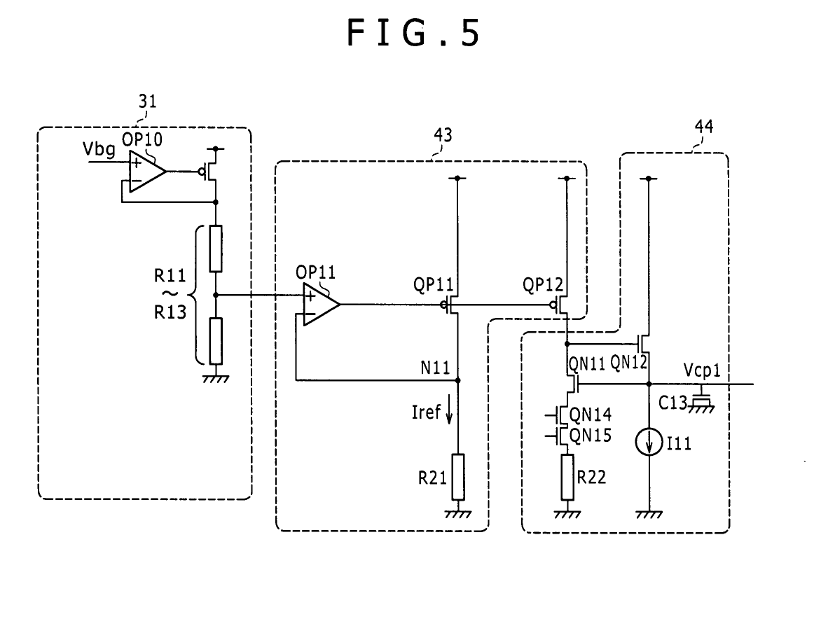

In the voltage conversion circuit 32 configured as described above, the NMOS transistors QN11 to QN15 cancel out the variations in threshold voltages of the clamping transistors QN21 and QN22 (QN23 and QN24) in such a manner as not to affect the voltage detected by the input terminal of the sense amplifier. Similarly, the voltage conversion circuit 32 cancels out the variations in threshold voltages of the column selection transistors QN23 and QN24 (QN33 and QN34) in such a manner as not to affect the voltage detected by the input terminal of the sense amplifier. When data is read from the memory cell MC, an extremely small voltage sufficiently lower than the source voltage is applied to the bit line BL. Minimizing the impact of variations in capabilities of the clamping transistors QN21 and QN22 and column selection transistors QN23 and QN24 provides highly accurate control. This prevents data corruptions due to disturbance. It should be noted that although not illustrated, the sense amplifier 45 is configured in the same manner as the existing sense amplifier 52 shown in FIG. 5.

It should be noted that a switch SW13 is switched according to the nature of read control implemented. There are three types of read control, namely, normal read, write verify and erase verify. Normal read is a normal read operation adapted to read data from the memory cell MC. Write verify is a data read operation performed after data write to verify whether the data has been properly written to the memory cell MC. Erase verify is a data read operation performed after data erasure by overwriting to verify whether the data has been properly erased from the memory cell MC. The switch SW13 selects the control voltage Vcp1 of the first voltage conversion circuit 40 for normal read, the control voltage Vcp2 of the second voltage conversion circuit 41 for write verify and the control voltage Vcp3 of the third voltage conversion circuit 42 for erase verify.

Here, the resistors R21 and R22 are variable resistors. It is possible to respond to the variations in resistive component (current driving capability) of the memory cell MC by using the resistors R21 and R22 with controllable resistances.

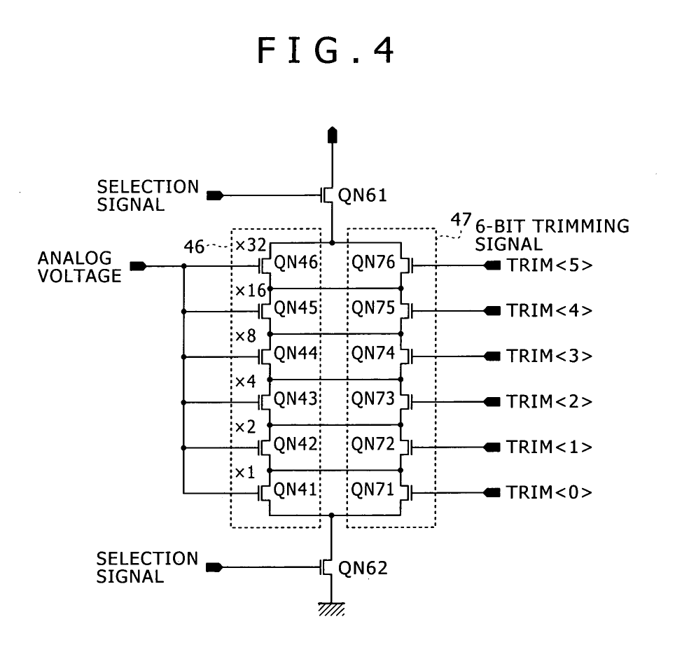

The resistors R21 and R22 can each be made up of a plurality of MOS transistors. FIG. 4 illustrates a specific example of a variable resistor made up of MOS transistors.

As illustrated in FIG. 4, this variable resistor includes a variable resistor section 46 and resistor selection switch section 47. The variable resistor section 46 includes NMOS transistors QN41 to QN46 that are connected in series. The resistor selection switch section 47 includes NMOS transistors QN71 to QN76 that can short out the NMOS transistors QN41 to QN46, respectively.

The variable resistor section 46 is configured so that the NMOS transistors QN41 to QN46 are one-fold, two-fold, four-fold and so on up to thirty-two-fold in size, respectively, and that a given voltage is applied to the gates of the NMOS transistors QN41 to QN46.

The NMOS transistors QN71 to QN76 are controlled by trimming signals TRIM(0) to TRIM(5), respectively, to selectively short out these NMOS transistors QN41 to QN46. Because the resistance of the variable resistor section 46 is controlled by the six-bit trimming signals as described above, 64 possible resistances are available to choose from.

This provides an extremely wide range over which the resistances of the resistors R21 and R22 can be changed. Such an extremely wide range is extremely effective for read operations from a resistance change nonvolatile storage device whose memory devices undergo a change in resistance by two to three orders of magnitude.

It should be noted that this variable resistor has selection transistors QN61 and QN62. These transistor QN61 and QN62 are each controlled to turn ON or OFF by a selection control signal. When the selection transistors QN61 and QN62 are both OFF, no current flows through the NMOS transistors QN41 to QN46. Therefore, leaving these selection transistors QN61 and QN62 OFF when no data is read contributes to power saving.

On the other hand, the same device as that used for the memory cell MC may be used for the variable resistor section 46 rather than the NMOS transistors QN41 to QN46. This allows for the voltage of the bit line BL to be more responsive, thus minimizing the impact of process variations.

### [4. Another Configuration of the Data Read Circuit]

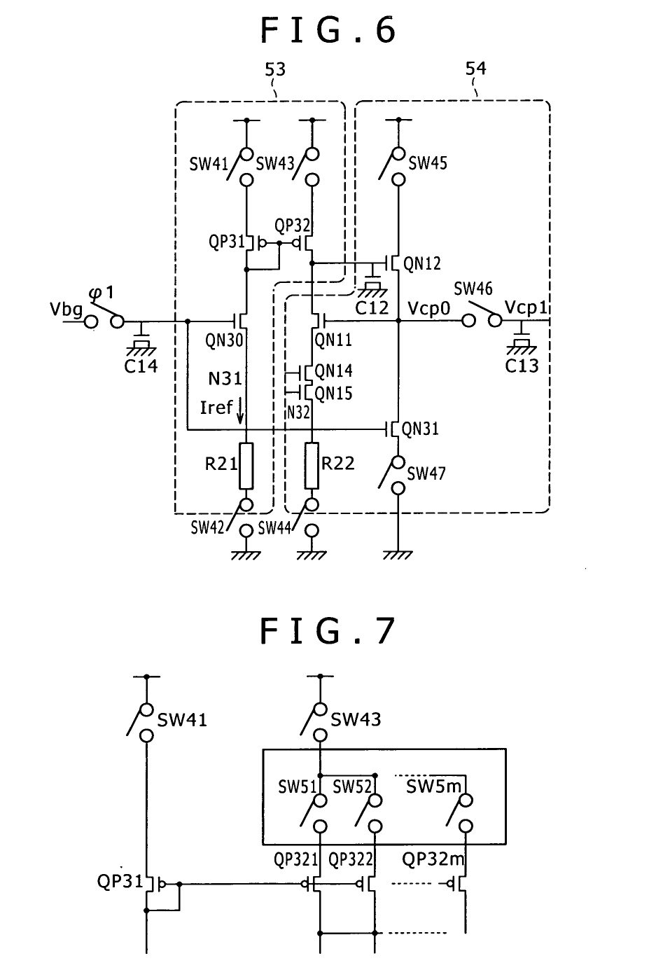

A description will be given next of another example of the data read circuit in the nonvolatile storage device according to the present embodiment with reference to the accompanying drawings. The data read circuit according to the present specific example is designed to control the voltage applied to the bit lines without using any feedback operational amplifier. FIG. 5 is a simplified diagram illustrating the configuration of the data read circuit according to the present embodiment. FIG. 6 is a simplified diagram illustrating the configuration of the data read circuit in another specific example according to the present invention.

The data read circuit according to the present embodiment (refer to FIG. 3) can be simplified into a circuit as shown in FIG. 5. That is, when compared with the data read circuit illustrated in FIG. 3, that illustrated in FIG. 5 is devoid of the switch SW11 in the reference voltage generation circuit 31, the MOS capacitor C11 in the first regulator section 43 and the MOS capacitor C12, NMOS transistor QN12, switch SW12 and constant current source I12 in the second regulator section 44.

In contrast to the above data read circuit (refer to FIG. 5), the data read circuit according to the present specific example includes a reference voltage generation circuit 53, regulator circuit 54 and other components as illustrated in FIG. 6.

The reference voltage generation circuit 53 is an integration of the reference voltage generation circuit 31 and first regulator section 43 described above to offer the same capabilities as the control voltage generation circuit 30. The same circuit 53 generates the reference voltage Vref based on the low-voltage and high-accuracy band gap reference voltage Vbg output from the band gap reference circuit (not shown) using a CMOS process.

The reference voltage generation circuit 53 includes an NMOS transistor QN30, the PMOS transistors QP31 and QP32 and resistor R21 as illustrated in FIG. 6. The PMOS transistor QP31 has its source connected to the source voltage Vdd via a switch SW41 and its drain connected to the drain of the NMOS transistor QN30. On the other hand, the NMOS transistor QN30 has its gate connected to the band gap reference circuit (not shown) via the switch SW11 and its source connected to one end of the resistor R21. The other end of the resistor R21 is connected to ground via a switch SW42. A MOS capacitor C14 is connected between the gate of the NMOS transistor QN30 and the switch SW11.

The PMOS transistor QP32 has its source connected to the source voltage Vdd via a switch SW43 and its drain connected to the gate of the NMOS transistor QN12 making up the regulator circuit 54 which will be described later. Further, the PMOS transistor QP32 has its gate connected to the gate of the PMOS transistor QP31. As a result, the PMOS transistors QP31 and QP32 form a current mirror.

On the other hand, the regulator circuit 54 includes the NMOS transistors QN11, QN12, QN14, QN15 and QN31, MOS capacitors C12 and 013 and resistor R22. The NMOS transistor QN11 has its drain connected to the drain of the PMOS transistor QP32 making up the reference voltage generation circuit 53 and its source connected to the drain of the NMOS transistor QN14. Further, the NMOS transistor QN14 has its source connected to the drain of the NMOS transistor QN15 whose source is connected to one end of the resistor R22. Still further, the other end of the resistor R22 is connected to ground via a switch SW44.

The NMOS transistor QN12 has its drain connected to the source voltage Vdd via a switch SW45. Further, the same transistor QN12 has its source connected to the gate of the NMOS transistor QN11 and the drain of the NMOS transistor QN31. Still further, a control voltage Vcp0 is output from the source of the NMOS transistor QN12. Still further, the NMOS transistor QN12 has its source connected to the MOS capacitor C13 via a switch SW46.

The NMOS transistor QN31 has its source connected to ground via a switch SW47 and its gate connected between the NMOS transistor QN30 and the MOS capacitor C14.

In the data read circuit configured as described above, when the band gap reference voltage Vbg is applied to the gate of the NMOS transistor QN30 making up the reference voltage generation circuit 53, the potential of a node N31 is determined by the band gap reference voltage Vbg, the threshold of the NMOS transistor QN30 and the resistor R21.

That is, a current Iref (reference current) flowing through the resistor R21 can be expressed by the following equation where Vth1 is the threshold of the NMOS transistor QN30:

Iref=(Vbg−Vth1)/R21

As a result, the current Iref is equal to the current flowing through the PMOS transistor QP31.

In the PMOS transistors QP31 and QP32 forming a current mirror circuit, the current flowing through the PMOS transistor QP31 is copied to the PMOS transistor QP32.

Here, the ratio of current flow between the PMOS transistors QP31 and QP32 is determined by the ratio of capability between the two transistors QP31 and QP32. We assume here that the capability is determined by the transistor gate width, and the gate width of the PMOS transistor QP31 is denoted by W31, and the gate width of the PMOS transistor QP32 is denoted by W32.

That is, the current flowing through the resistor R22 can be expressed by the following equation:

(Vbg−Vth1)/R21×W32/W31

Therefore, the voltage appearing at a node N32 can be expressed by the following equation:

(Vbg−Vth1)×R22/R21×W32/W31

Then, the voltage appearing at Vcp0 can be expressed by the following equation where Vth2 is the threshold of the NMOS transistor QN11:

Vcp0=(Vbg−Vth1)×R22/R21×W32/W31+Vth2

Vcp0=Vcp1 (when Φ3 is ON).

As described above, the voltage at Vcp1 can be adjusted by adjusting the capabilities of the given gate widths W32 and W31, thus making it possible to control the potential VBL of the bit line BL (refer to FIG. 3). As a result, a low power consumption system can be configured without using the operational amplifiers OP10 and OP11.

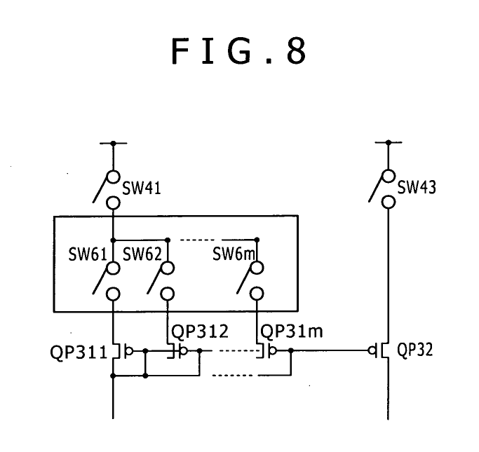

A description will be given next of an example of means for changing the capabilities of the gate width W31 of the PMOS transistor QP31 and gate width W32 of the PMOS transistor QP32. FIG. 7 is a diagram illustrating means for changing the capability of the PMOS transistor QP32 with the gate width W32. FIG. 8 is a diagram illustrating means for changing the capability of the PMOS transistor QP31 with the gate width W31.

As an example of means for changing the capabilities of the gate widths W31 and W32, a plurality of PMOS transistors QP32₁ to QP32ₘ connected in parallel can be, for example, provided as the PMOS transistor QP32 making up a current mirror circuit as illustrated in FIG. 7. Switches SW5₁ to SW5ₘ are provided respectively between the sources of the PMOS transistors QP32₁ to QP32ₘ and the switch SW43 so that the PMOS transistors QP32₁ to QP32ₘ can be operated independently of each other.

In the example shown in FIG. 7, a decoding signal is applied to the desired ones of the switches SW5₁ to SW5ₘ to change the PMOS transistors QP32₁ to QP32ₘ to be operated, thus adjusting the capabilities of the gate widths W31 and W32. This changes the capability of the gate width W32.

As another example of means for changing the capabilities of the gate widths W31 and W32, a plurality of PMOS transistors QP31₁ to QP31ₘ connected in parallel can be, for example, provided as the PMOS transistor QP31 making up a current mirror circuit as illustrated in FIG. 8. Switches SW6₁ to SW6ₘ are provided respectively between the sources of the PMOS transistors QP31₁ to QP31ₘ and the switch SW41 so that the PMOS transistors QP31₁ to QP31ₘ can be operated independently of each other. This changes the capability of the gate width W31.

In the example shown in FIG. 8, a decoding signal is applied to the desired ones of the switches SW6₁ to SW6ₘ to change the PMOS transistors QP31₁ to QP31ₘ to be operated, thus adjusting the capabilities of the gate widths W31 and W32.

It should be noted that although, in the examples shown in FIGS. 7 and 8, a switching circuit is provided either in the PMOS transistor QP31 or QP32, the present invention is not limited thereto. Instead, a switching circuit may be provided in both the PMOS transistors QP31 and QP32. In order to change the capabilities of the gate widths W31 and W32, on the other hand, only one of the PMOS transistors or a plurality thereof may be selected with a decoding signal.

In the method shown in FIG. 3, the data read circuit must be ON at all times to control the VBL potential. In the method according to the present specific examples, on the other hand, switches SW are provided for Φ1 to Φ3 so that the data read circuit can be operated intermittently. When the data read circuit is shut down, the potential at Vcp0 is held by the MOS capacitor C13 for use as the potential at Vcp1, thus contributing to reduced power consumption as compared to the operation with the circuit left ON at all times.

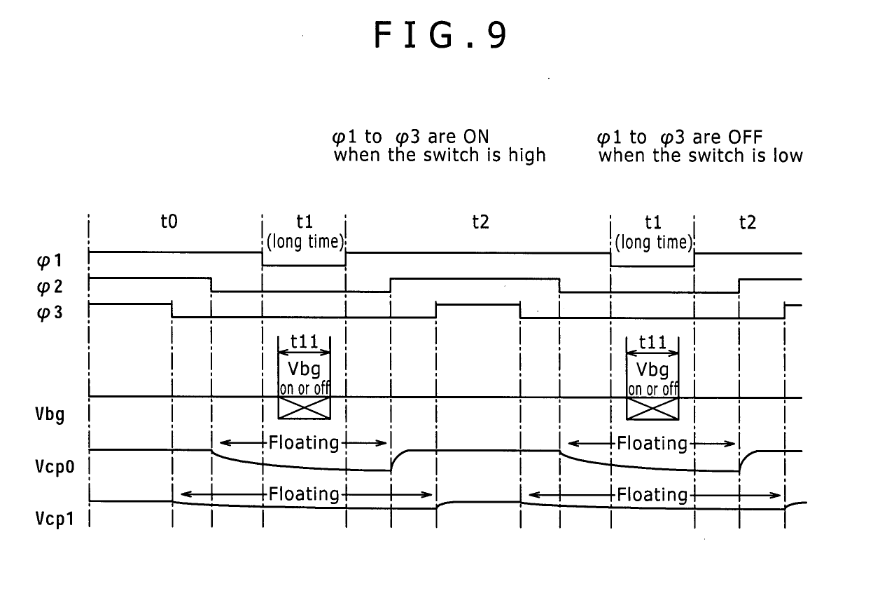

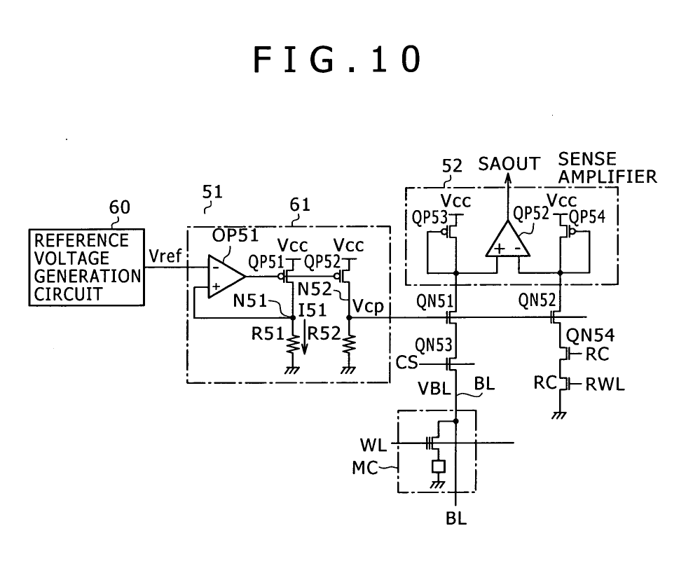

A description will be given next of the intermittent operation of the data read circuit according to the present specific example. FIG. 9 is a diagram describing the intermittent operation of the data read circuit according to the present specific example. In FIGS. 9, Φ1 to Φ3 are ON when the switches SW are high and OFF when the switches SW are low.

As illustrated in FIG. 9, Vcp1 is stabilized during a period t0, and Φ3 is pulled down to low level to disconnect Vcp1 so that the potential at Vcp1 is held by the capacitance of the MOS capacitor C13.

Next, Φ2 is pulled down to low level to bring the reference voltage generation circuit 53 and regulator circuit 54 into a floating condition, thus removing the operating current.

Next, Φ1 is pulled down to low level to make the MOS capacitor C14 to hold the potential of the band gap reference voltage Vbg. This operation assumes the intermittent operation of the reference voltage circuit to ensure low power consumption in the operation of the reference voltage circuit. However, if the reference voltage circuit is always ON or Vbg is always held, that is, if the reference voltage circuit performs sample-and-hold operation, the switch SW for Φ1 is not required.

During a t1 period (long), the potential of Vcp1 is held by the capacitance of the MOS capacitor C13. Because of the presence of the switch SW for Φ1, the reference voltage circuit which supplies the band gap reference voltage Vbg may be ON at all times or be OFF for reduced power consumption.

During a period t2, the switch SW for Φ1 is pulled up to high level to transfer the band gap reference voltage Vbg to the NMOS transistors QN30 and QN31 of the reference voltage generation circuit 53. Next, Φ2 is pulled up to high level to enable the reference voltage generation circuit 53 and regulator circuit 54 and bring Vcp0 to the set voltage.

Then, Φ3 is pulled up to high level to connect Vcp0 and Vcp1 together and reactivate Vcp1. When the recharging of Vcp1 is complete, Φ3, Φ2 and Φ1 are pulled down to low level in this order to proceed to the operation during the period t1. The operation cycle is repeated from t1 to t2, to t1 and so on. This allows for the reference voltage generation circuit 53 and regulator circuit 54 to operate intermittently, thus contributing to reduced power consumption as compared to the operation with the two circuits left ON at all times.

As described above, the Φ1 signal assumes that the reference voltage circuit also operates intermittently for reduced power consumption. However, if the reference voltage circuit is always ON or the band gap reference voltage Vbg is always held, that is, if the reference voltage circuit performs sample-and-hold operation, the switch SW for Φ1 is not required.

As described above, the data read circuit according to the present specific example can generate the reference voltage Vref from the band gap reference voltage Vbg and NMOS transistors without using any feedback operational amplifier. This makes it possible to control the voltage applied to the bit line and allows for simplification of the circuits.

Further, the foldback current is adjusted with the PMOS size, thus making it also possible to adjust the bias voltage.

Still further, a sample/hold circuit is provided for intermittent operation, thus allowing for low power consumption in operation.

Although the preferred embodiment of the present invention has been described in detail with reference to several accompanying drawings, what has been described herein is merely illustrative. It should be understood that the present invention can be carried out in other modes to which various modifications and improvements are applied based on knowledge of those skilled in the art.

The present application contains subject matter related to that disclosed in Japanese Priority Patent Application JP 2010-259714 filed in the Japan Patent Office on Nov. 22, 2010, and in Japanese Priority Patent Application JP 2010-054199 filed in the Japan Patent Office on Mar. 11, 2010, the entire contents of which are hereby incorporated by reference.

What is claimed is:

1. A control voltage generation circuit comprising:
a reference voltage generation circuit adapted to generate a reference voltage; and
a voltage conversion circuit adapted to generate, based on the reference voltage, a control voltage to be supplied to the gate of a clamping transistor connected between a bit line and a sense amplifier to adjust the voltage of the bit line, wherein
the voltage conversion circuit outputs a voltage, which is the sum of a voltage proportional to the reference voltage and a voltage equivalent to the threshold voltage of the clamping transistor, to the gate of the clamping transistor as the control voltage.

2. The control voltage generation circuit of claim 1 comprising:
variable resistors adapted to adjust the control voltage.

3. A nonvolatile memory device comprising:
a memory cell array having memory cells arranged in a matrix form;
word lines each of which is connected to the memory cells in the same row;
bit lines each of which is connected to the memory cells in the same column;
sense amplifiers each of which is fed with a signal read from the memory cell connected to the word line in the row selected as the target row via the bit line at one of the input terminals, and each of which is fed with a signal read from a reference cell at the other input terminal;
clamping transistors each of which is connected between one of the sense amplifiers and one of the bit lines and adjusts the voltage of the bit line by using a control voltage applied to the gate; and
a control voltage generation circuit adapted to generate the control voltage, wherein
the control voltage generation circuit includes:
a reference voltage generation circuit adapted to generate a reference voltage; and
voltage conversion circuits each of which outputs a voltage, which is the sum of a voltage proportional to the reference voltage and a voltage equivalent to the threshold voltage of the clamping transistor, to the gate of the clamping transistor as the control voltage.

4. The nonvolatile memory device of claim 3, wherein
the voltage conversion circuit includes variable resistors adapted to adjust the control voltage.
